(19) United States
(12) Patent Application Publication
(10) Pub. No.: US 2008/0084232 A1
(43) Pub. Date: Apr. 10, 2008

(54) NEGATIVE VOLTAGE DETECTOR

(75) Inventors: Chao Hsing Huang, Hsinchu (TW); Chih Chi Hsu, Hsinchu (TW); Chun Liang Yeh, Hsinchu (TW)

Correspondence Address: EGBERT LAW OFFICES, 412 MAIN STREET, 7TH FLOOR, HOUSTON, TX, 77002, US

(73) Assignee: ADVANCED ANALOG TECHNOLOGY, Inc., Hsinchu (TW)

(21) Appl. No.: 11/557,600

(22) Filed: Nov. 8, 2006

(30) Foreign Application Priority Data
Sep. 13, 2006 (TW) 095133806

(51) Int. Cl. H03K 5/22

(52) U.S. Cl. 327/77

(57) ABSTRACT

A negative voltage detector includes a first n-channel transistor having a coupled gate node and drain node, a second n-channel transistor having a gate coupled to the gate of the first n-channel transistor, a first current source coupled to a drain of the first n-channel transistor, a second current source coupled to a drain of the second n-channel transistor, an output terminal coupled to the drain of the second n-channel transistor, and an input terminal coupled to a source of the first n-channel transistor. The gate voltage of the first n-channel transistor, i.e., the gate voltage of the second n-channel transistor, depends on its source voltage (the voltage of the input terminal), and the switching operation of the second n-channel transistor can be performed by controlling the voltage of the input terminal to change the output voltage of the output terminal.

### CROSS-REFERENCE TO RELATED U.S. APPLICATIONS

Not applicable.

### STATEMENT REGARDING FEDERALLY SPONSORED RESEARCH OR DEVELOPMENT

Not applicable.

### NAMES OF PARTIES TO A JOINT RESEARCH AGREEMENT

Not applicable.

### REFERENCE TO AN APPENDIX SUBMITTED ON COMPACT DISC

Not applicable.

### BACKGROUND OF THE INVENTION

1. Field of the Invention

The present invention relates to a negative voltage detector, and more particularly, to a negative voltage detector using a current mirror.

2. Description of Related Art Including Information Disclosed Under 37 CFR 1.97 and 37 CFR 1.98.

FIGS. 1 and 2 show a conventional negative voltage detector 10 and its voltage variation. The negative voltage detector 10 includes a comparator 12 and a voltage-dividing circuit 14. The voltage-dividing circuit 14 includes two resistors (R1, R2), and the relation of the output voltage (V_{S}) and the voltage (V_{N}) under detect are V_{S}=(V₁−V_{N})·R₂/(R₁+R₂). An output terminal of the comparator 12 is coupled to two series-connected inverters 16, 18, the positive input terminal of the comparator 12 is coupled to a reference voltage (V_{REF}), and the negative input terminal of the comparator 12 is coupled to an output terminal of the voltage-dividing circuit 14.

When the reference voltage (V_{REF}) is less than the output voltage (V_{S}) of the voltage-dividing circuit 14, the output voltage of the comparator 12 is low. As the voltage (V_{N}) under detect decreases toward the negative to a predetermined negative voltage (V_{X}), the output voltage (V_{S}) of the voltage-dividing circuit 14 is less than the reference voltage (V_{REF}) such that the output voltage of the comparator 12 increases from a low to a high level. Briefly, the negative voltage detector 10 detects the output voltage (V_{S}) less than the reference voltage (V_{REF}) using the comparator 12, and the output voltage (V_{S}) of the voltage-dividing circuit 14 depends on V₁, R₁ and R₂ thereof. Therefore, the negative voltage detector 10 can be used to detect different values of the predetermined negative voltages (V_{X}) by changing V₁, R₁ and R₂ of the voltage-dividing circuit 14. However, it is necessary to use a resistor R₁ and R₂ in the voltage-dividing circuit 14, i.e., a large wafer area may be needed, so it is very cost-consuming to be implemented as applied to integrated circuits.

FIGS. 3 and 4 show another conventional negative voltage detector 200 using a source follower design and its voltage variation, which is disclosed in U.S. Pat. No. 6,549,016 B1. The negative voltage detector 200 includes two p-channel transistors 201, 202 and an inverter 203. A drain node of the p-channel transistor 201 is connected to a source node of the p-channel transistor 202, an input terminal of the inverter 203 is coupled to a connecting node N1 of the p-channel transistors 201, 202, and the voltage (V_{NN}) under detect is coupled to a gate node of the p-channel transistor 202.

A source node of the p-channel transistor 201 is coupled to a positive voltage (V_{CC}) and a gate node of the p-channel transistor 201 is grounded, so the p-channel transistor 201 is always turned on. When the voltage (V_{NN}) under detect is higher than a threshold voltage (Vₜₕ) of the p-channel transistor 202, the p-channel transistor 202 is turned off, the voltage (V_{DIV}) of the connecting contact N1 is at a high level, and the output voltage of the inverter 203 is at a low level. As the voltage (V_{NN}) under detect decreases toward a negative level to be lower than the threshold voltage of the p-channel transistor 202, the p-channel transistor 202 is turned on, and the voltage (V_{DIV}) of the connecting contact N1 varies as the voltage (V_{NN}) under detect since the negative voltage detector 200 uses the source follower design.

After the p-channel transistor 202 is turned on, the turn-on resistance declines as the voltage (V_{NN}) under detect becomes more negative, and the voltage (V_{DIV}) of the connecting contact N1 reduces correspondingly. When the voltage (V_{DIV}) of the connecting contact N1 declines to a trigger voltage (V_{TRIP}) of the inverter 203, the output voltage of the inverter 203 is converted to a high level from a low level such that the voltage (V_{NN}) under detect at the negative level is converted into a high level voltage. Particularly, the output voltage of the inverter 203 depends on whether the voltage (V_{DIV}) of connecting contact N1 is less than the trigger voltage (V_{TRIP}), and the voltage (V_{DIV}) of connecting contact N1 further depends on the ratio of the turn-on resistance (i.e. the width and the length) of the p-channel transistors 201, 202. Therefore, the contact voltage (V_{DIV}) triggering the inverter 203, i.e., the voltage (V_{NN}) under detect, can be determined by appropriate selection of the ratio of the turn-on resistance of the p-channel transistors 201, 202.

### BRIEF SUMMARY OF THE INVENTION

One aspect of the present invention provides provide a negative voltage detector using a current mirror.

A negative voltage detector according to this aspect of the present invention includes a first n-channel transistor having a gate node and a drain node coupled to the gate node, a second n-channel transistor having a gate node coupled to the gate node of the first n-channel transistor, a first current source coupled to the drain node of the first n-channel transistor, a second current source coupled to a drain node of the second n-channel transistor, an output terminal coupled to the drain node of the second n-channel transistor, and an input terminal coupled to a source node of the first n-channel transistor. The input terminal can control the switching operation of the second n-channel transistor by controlling the gate node voltage of the second n-channel transistor, so as to change the output voltage of the output terminal.

The output current of the first current source can be larger than that of the second current source, and the width over length (W/L) ratio for the first n-channel transistor is substantially the same as that for the width over length ratio of the second n-channel transistor. Preferably, the first current source includes a first p-channel transistor, the second current source includes a second p-channel transistor, and the width over length ratio of the first p-channel transistor is larger than the width over length ratio of the second p-channel transistor. In addition, the output current of the first current source can also be equal to the output current of the second current source, the width over length ratio of the first p-channel transistor is equal to the width over length ratio of the second p-channel transistor, and the width over length ratio of the first n-channel transistor is less than the width over length ratio of the second n-channel transistor.

The first p-channel transistor and the second p-channel transistor form a current mirror, and the source nodes of the first p-channel transistor and the second p-channel transistor are coupled to a voltage source. The first n-channel transistor and the second n-channel transistor are high voltage transistors. The negative voltage detector can further include a negative voltage isolation element disposed between the first current source and the first n-channel transistor. The negative isolation element includes a p-channel transistor having a source node coupled to the first current source and a drain node coupled to the drain node of the first n-channel transistor.

### BRIEF DESCRIPTION OF THE SEVERAL VIEWS OF THE DRAWINGS

The objectives and advantages of the present invention will become apparent upon reading the following description and upon reference to the accompanying drawings.

FIGS. 1 and 2 show a schematic view and graph illustration, respectively, of a conventional negative voltage detector and its voltage variation.

FIGS. 3 and 4 show a schematic view and graph illustration, respectively, of another conventional negative voltage detector and its voltage variation.

FIGS. 5 and 6 show a schematic view and graph illustration, respectively, of a negative voltage detector and its voltage variation according to one embodiment of the present invention.

FIG. 7 shows another schematic view of a negative voltage detector according to another embodiment of the present invention.

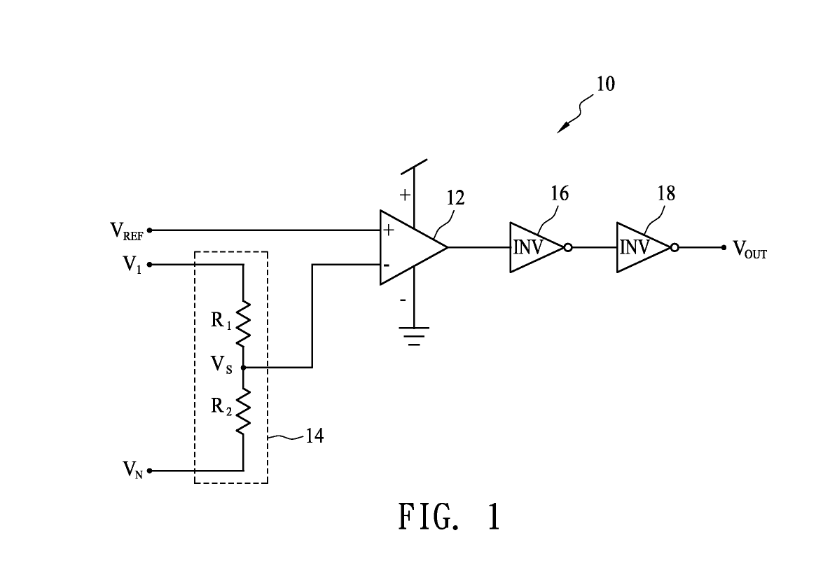

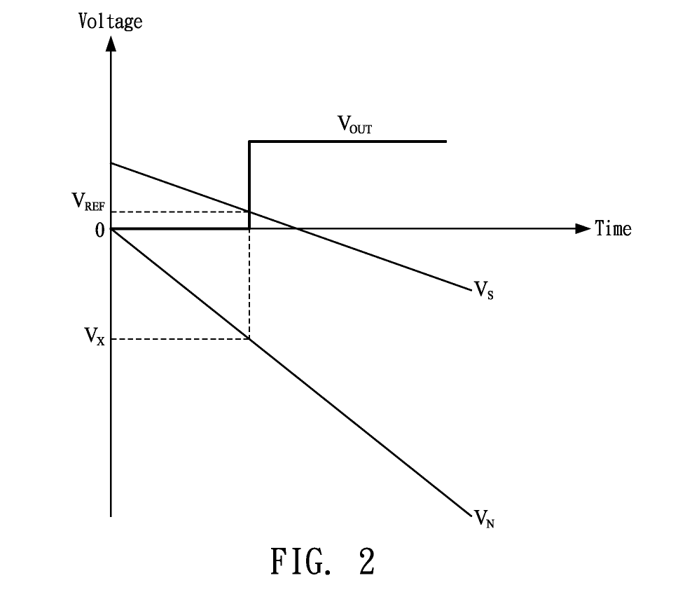

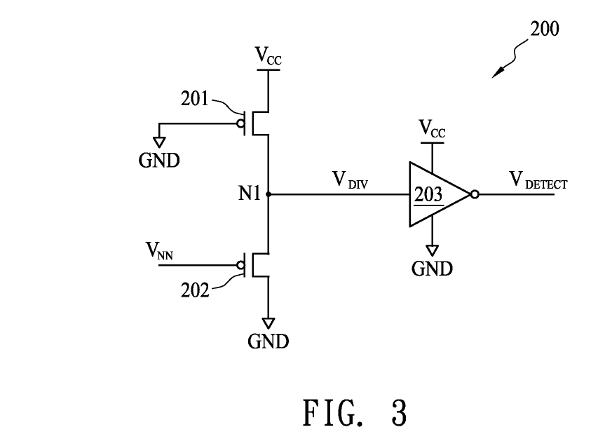

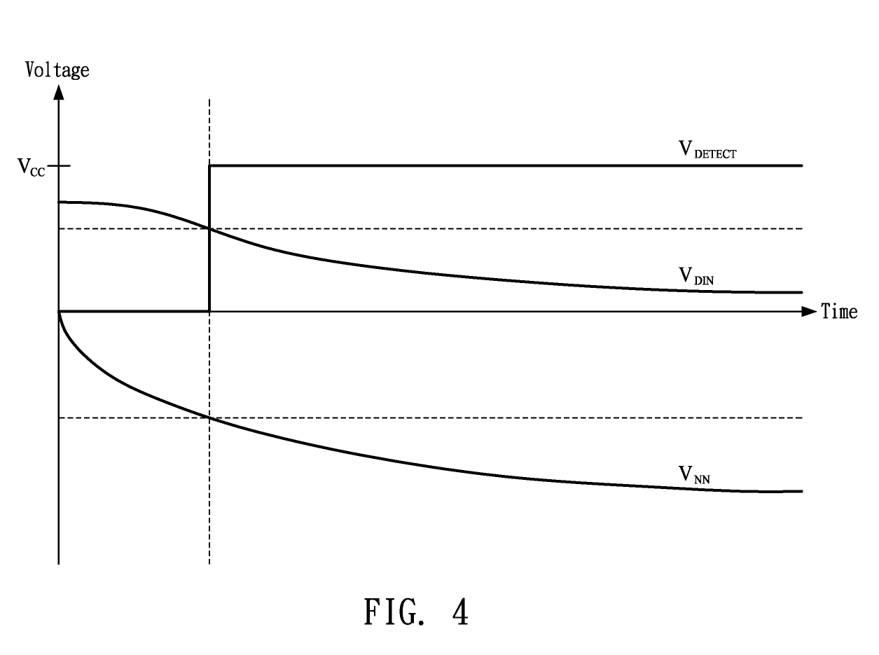

### DETAILED DESCRIPTION OF THE INVENTION

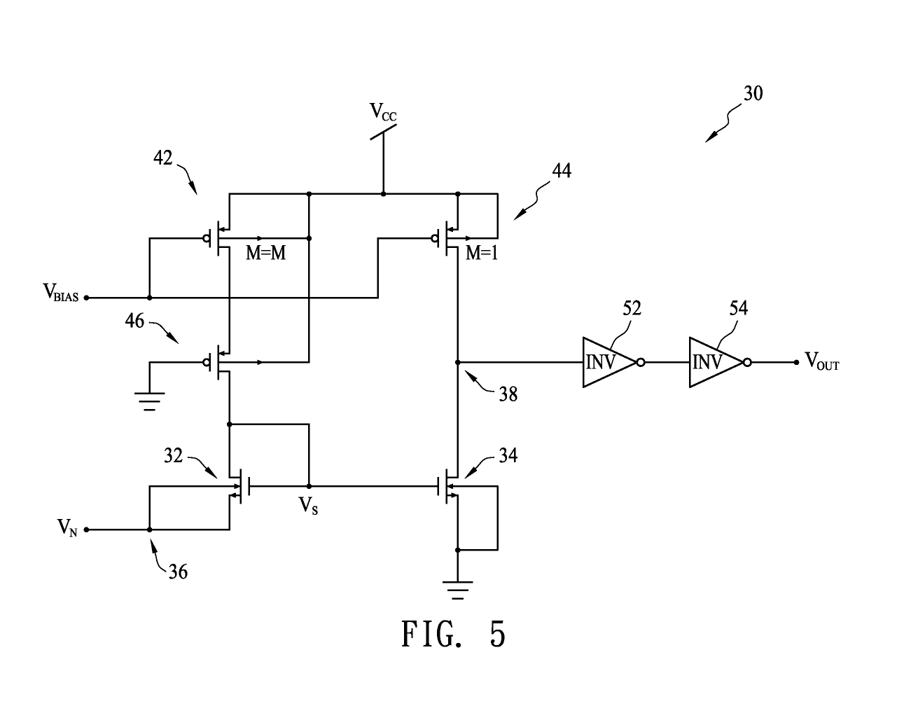

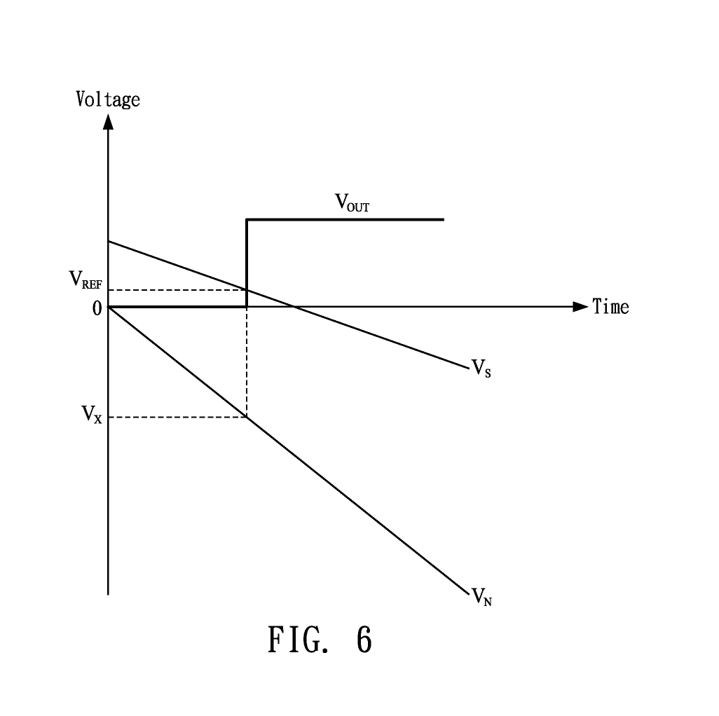

FIGS. 5 and 6 show a negative voltage detector 30 and its voltage variation according to one embodiment of the present invention. The negative voltage detector 30 includes a first n-channel transistor 32 having a coupled gate node and drain node, a second n-channel transistor 34 having a gate node coupled to the gate node of the first n-channel transistor 32, a first current source 42 coupled to the drain node of the first n-channel transistor 32, a second current source 44 coupled to a drain node of the second n-channel transistor 34, an output terminal 38 coupled to the drain node of the second n-channel transistor 34, and an input terminal 36 coupled to a source node of the first n-channel transistor 32. Specifically, the gate nodes of the first n-channel transistor 32 and the second n-channel transistor 34 are connected to a gate node voltage (V_{S}), which varies as the voltage (V_{N}) under detect since the first n-channel transistor 32 operates in the saturation region. In addition, the negative voltage detector 30 can further include two series-connected inverters 52, 54 coupled to the output terminal 38.

The first n-channel transistor 32 and the second n-channel transistor 34 can be high-voltage NMOS transistors. The negative voltage detector 30 can further include a negative voltage isolation element 46 disposed between the first current source 42 and the first n-channel transistor 32. The negative voltage isolation element 46 includes a p-channel transistor having a source node coupled to the first current source 42 and a drain node coupled to the drain node of the first n-channel transistor 32. Preferably, the p-channel transistor is a high-voltage PMOS transistor, and has the gate node connected to ground to prevent the negative voltage of the first n-channel transistor 32 from propagating to the first current source 42.

The output current of the first current source 42 can be larger than the output current of the second current source 44, and the width over length ratio for the first n-channel transistor 32 is substantially the same as that for the width over length ratio of the second n-channel transistor 34, i.e., the first n-channel transistor 32 matches the second n-channel transistor 34. Preferably, the first current source 42 includes a first p-channel transistor, the second current source 44 includes a second p-channel transistor, and the width over length ratio (M=M) of the first p-channel transistor can be larger than the width over length ratio (M=1) of the second p-channel transistor. In this manner, the current provided by the first current source 42 to the first n-channel transistor 32 is larger than the current provided by the second current source 44 to the second n-channel transistor 34. Particularly, the first current source 42 may be formed by M pieces of second p-channel transistors (width over length ratio M=1) connected in parallel. The first p-channel transistor and the second p-channel transistor can be PMOS transistors, and the source nodes of the first p-channel transistor and the second p-channel transistor are coupled to a voltage source (V_{CC}) to form a current mirror.

The first n-channel transistor 32 operates in a saturation region, the gate node voltage depends on the voltage of the source node (i.e. the input terminal 36), and the gate node of the second n-channel transistor 34 is coupled to the gate node of the first n-channel transistor 32. Consequently, the input terminal 36 can control the switching operation of the second n-channel transistor 34 by controlling the gate node voltage of the second n-channel transistor 32 so as to change the output voltage of the output terminal 38. The source node of the second n-channel transistor 34 is grounded, the second n-channel transistor 34 is turned on when the gate node voltage (V_{S}) of the second n-channel transistor 34 is larger than the threshold voltage, and the output voltage of the output terminal 38 is at a low level.

The input terminal 36 is coupled to a voltage (V_{N}) under detect. As the voltage (V_{N}) under detect decreases toward a negative level to a predetermined negative voltage (V_{X}), the gate node voltage (V_{S}) of the first n-channel transistor 32 (i.e. the gate node voltage of the second n-channel transistor 34) declines correspondingly. When the gate node voltage (V_{S}) declines to lower than a reference voltage (V_{REF}) (i.e. the threshold voltage of the second n-channel transistor 34), the second n-channel transistor 34 is turned off, the voltage of the output terminal 38 is converted from a low level to a high level, and the output voltage (V_{OUT}) passing through the two series-connected inverters 52, 54 is at a high level.

Particularly, the current provided by the first current source 42 to the first n-channel transistor 32 is larger than the current provided by the second current source 44 to the second n-channel transistor 34, and the source node of the second n-channel transistor 34 is grounded. Therefore, when the gate node voltage (V_{S}) of the first n-channel transistor 32 (i.e. the gate node voltage of the second n-channel transistor 34) declines to the reference voltage (V_{REF}) (i.e. the threshold voltage of the second n-channel transistor 34), the voltage (V_{N}) under detect coupled to the source of the first n-channel transistor 32 must be a negative voltage (V_{X}). In this manner, the value of the negative voltage (V_{X}) can be changed by changing the ratio of the current provided by the first current source 42 to the first n-channel transistor 32 and the current provided by the second current source 44 to the second n-channel transistor 34.

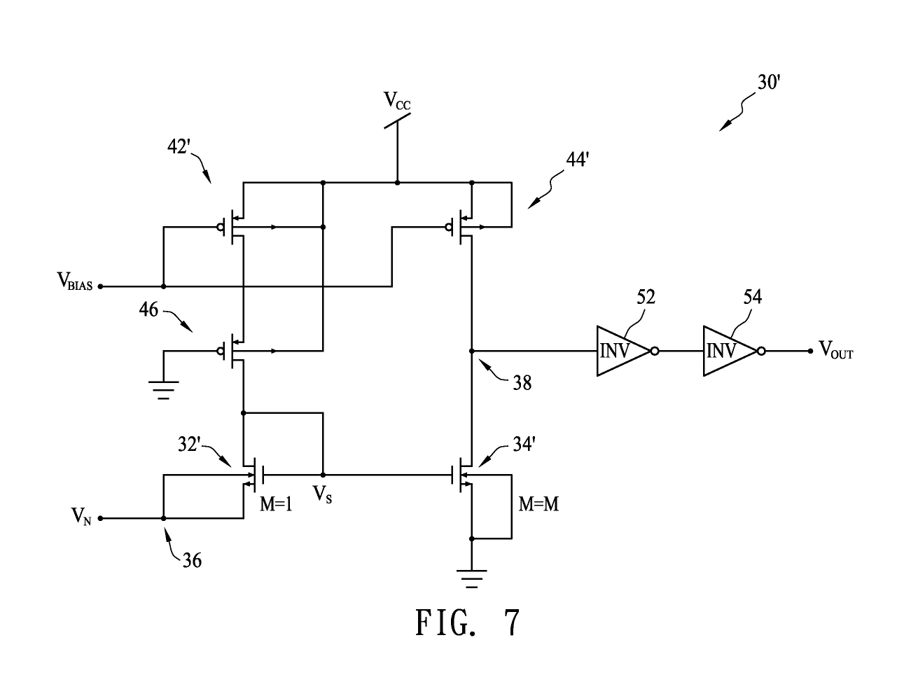

FIG. 7 shows a negative voltage detector 30′ according to another embodiment of the present invention. Compared with the negative voltage detector 30 shown in FIG. 5 using the matched first n-channel transistor 32 and second n-channel transistor 34, the first n-channel transistor 32′ and second n-channel transistor 34′ of the negative voltage detector 30′ shown in FIG. 7 do not match each other. Particularly, the width over length ratio (M=1) of the first n-channel transistor 32′ is less than the width over length ratio (M=M) of the second n-channel transistor 34′. The second n-channel transistor 34′ can also be formed by M pieces of first n-channel transistors 32′ (width over length ratio M=1) connected in parallel.

The current provided by the first current source 42′ to the first n-channel transistor 32′ is equal to the current provided by the second current source 44′ to the second n-channel transistor 34′. That is, the first p-channel transistor matches the second p-channel transistor. The width over length ratio (M=1) of the first n-channel transistor 32′ is less than the width over length ratio (M=M) of the second n-channel transistor 34′, and the source of the second n-channel transistor 34 is grounded. Therefore, when the gate node voltage (V_{S}) of the first n-channel transistor 32′ (i.e. the gate node voltage of the second n-channel transistor 34) declines to the reference voltage (V_{REF}) (i.e. the threshold voltage of the second n-channel transistor 34), the voltage (V_{N}) under detect coupled to the source node of the first n-channel transistor 32′ must be a negative voltage (V_{X}). In this manner, the value of the negative voltage (V_{X}) is changed by changing the ratio of the width over length ratios of the first n-channel transistor 32′ and the second n-channel transistor 34′.

The above-described embodiments of the present invention are intended to be illustrative only. Numerous alternative embodiments may be devised by those skilled in the art without departing from the scope of the following claims.

1. A negative voltage detector, comprising:
a first n-channel transistor having a first gate node, a first drain node coupled to said first gate node, and a source node;
a second n-channel transistor having a second gate node coupled to said first gate node of said first n-channel transistor and a second drain node;
a first current source coupled to said first drain node of said first n-channel transistor;
a second current source coupled to said second drain node of said second n-channel transistor;
an output terminal coupled to said second drain node of said second n-channel transistor; and
an input terminal coupled to said source node of said first n-channel transistor and configured to control switching operation of said second n-channel transistor.

2. The negative voltage detector as claimed in claim 1, wherein output current of said first current source is larger than output current of said second current source.

3. The negative voltage detector as claimed in claim 2, wherein width over length ratio for said first n-channel transistor is substantially same as a width over length ration of said second n-channel transistor.

4. The negative voltage detector as claimed in claim 2, wherein said first current source comprises a first p-channel transistor, and wherein said second current source comprises a second p-channel transistor.

5. The negative voltage detector as claimed in claim 4, wherein the first p-channel transistor and the second p-channel transistor form a current mirror.

6. The negative voltage detector as claimed in claim 4, wherein width over length ratio for said first p-channel transistor is larger than width over length ratio for said second p-channel transistor.

7. The negative voltage detector as claimed in claim 4, wherein the first p-channel transistor and the second p-channel transistor have a source node coupled to a voltage source.

8. The negative voltage detector as claimed in claim 1, wherein the output current of the first current source is equal to the output current of the second current source.

9. The negative voltage detector as claimed in claim 8, wherein the width over length ratio of the first n-channel transistor is less than the width over length ratio of the second n-channel transistor.

10. The negative voltage detector as claimed in claim 8, wherein the first current source comprises a first p-channel transistor, and wherein the second current source comprises a second p-channel transistor.

11. The negative voltage detector as claimed in claim 10, wherein the first p-channel transistor and the second p-channel transistor form a current mirror.

12. The negative voltage detector as claimed in claim 10, wherein width over length ratio for said first p-channel transistor is substantially the same as width over length ratio for said second p-channel transistor.

13. The negative voltage detector as claimed in claim 10, wherein the first p-channel transistor and the second p-channel transistor have a source node coupled to a voltage source.

14. The negative voltage detector as claimed in claim 1, further comprising;
two inverters connected in series, said two inverters being coupled to said output terminal.

15. The negative voltage detector as claimed in claim 1, wherein the second n-channel transistor has a source node connected to ground.

16. The negative voltage detector as claimed in claim 1, wherein the first n-channel transistor and the second n-channel transistor are high-voltage NMOS transistors.

17. The negative voltage detector as claimed in claim 1, further comprising.
a negative voltage isolation element disposed between said first current source and said first n-channel transistor.

18. The negative voltage detector as claimed in claim 17, wherein said negative voltage isolation element further comprises a p-channel transistor, said p-channel transistor comprising:
a source node coupled to said first current source; and
a drain node coupled to said first drain node of said first n-channel transistor.

19. The negative voltage detector as claimed in claim 17, wherein the p-channel transistor is a high-voltage PMOS transistor.

20. The negative voltage detector as claimed in claim 1, wherein the first n-channel transistor operates in the saturation region.
